(19) United States
(12) Patent Application Publication
(10) Pub. No.: US 2025/0089576 A1
(43) Pub. Date: Mar. 13, 2025

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Chia-Hua LIN, Hsinchu (TW); Ming-Che KU, Hsinchu (TW); Min-Yung KO, Hsinchu (TW); Fu-Ting SUNG, Hsinchu (TW); Zhen-Yu GUAN, Hsinchu (TW)

(73) Assignee: Taiwan Semiconductor Manufacturing Company, Ltd., Hsinchu (TW)

(21) Appl. No.: 18/367,605

(22) Filed: Sep. 13, 2023

(51) Int. Cl. H10N 50/10; H10B 61/00; H10N 50/01; H10N 50/80

(52) U.S. Cl. CPC H10N 50/10; H10B 61/00; H10N 50/01; H10N 50/80

(57) ABSTRACT

A semiconductor structure includes a conductive layer, an IMD layer and a plurality of protrusions. The IMD layer is formed on the conductive layer and has a first etch rate. Each protrusion includes an etching slowing layer, a lower electrode and a MTJ layer, wherein the etching slowing layer is formed on the IMD layer and has a second etch rate, the lower electrode passes through the IMD layer and the etching slowing layer, and the MTJ layer is formed on the lower electrode. The second etch rate is less than the first etch rate.

### BACKGROUND

A conventional semiconductor structure may include a memory region including at least memory layer and a logic region. The memory layer including a plurality of layers which protrude relative to the logic region. However, such a prominent height may cause more photo masks required in manufacturing processes for the semiconductor structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a cross-sectional view of a semiconductor device according to an embodiment of the present disclosure;

FIG. 2 illustrates a schematic diagram of a cross-sectional view of a semiconductor device according to another embodiment of the present disclosure; and

FIGS. 3A to 3U illustrate schematic diagrams of manufacturing processes of the semiconductor device in FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

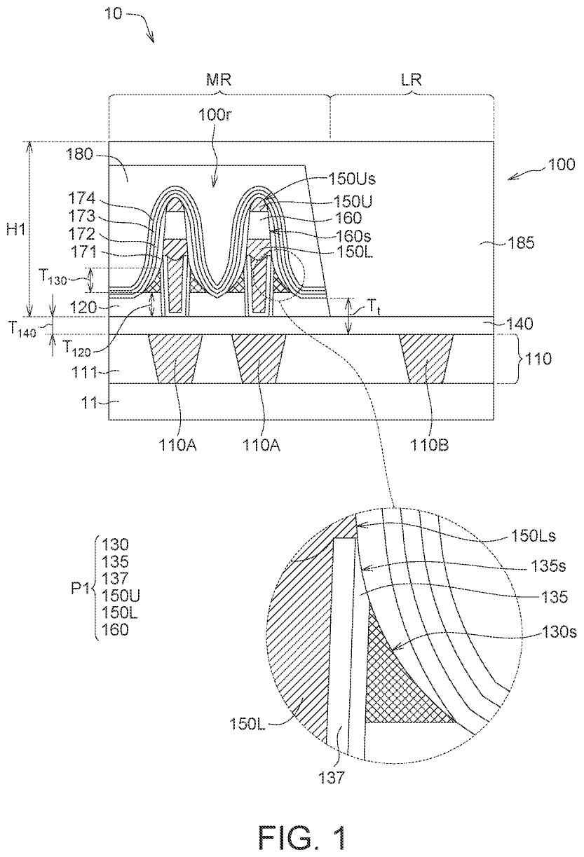

Referring to FIG. 1, FIG. 1 illustrates a schematic diagram of a cross-sectional view of a semiconductor device 10 according to an embodiment of the present disclosure.

As illustrated in FIG. 1, the semiconductor device 10 includes a FEOL (Front End of Line) structure 100 and a semiconductor structure 100 formed over the FEIOL structure 11. The semiconductor structure 100 is a BEOL (Back End of Line) structure or formed within the BEOL structure. The semiconductor structure 100 includes a conductive layer 110, an intermetal dielectric (IMD) layer 120, an etching stop layer 140 and a plurality of protrusions P1, a first covering layer 171, a second covering layer 172, a third covering layer 173, a fourth covering layer 174, an oxide layer 180 and a dielectric layer 185, wherein each protrusion P1 includes an etching slowing layer 130, a spacer layer 135, a barrier layer 137, a lower electrode 150L, an upper electrode 150U and a Magnetic Tunneling Junction (MTJ) layer 160.

As illustrated in FIG. 1, the semiconductor structure 100 includes, for example, a memory region MR and a logic region LR. In the present embodiment, the conductive layer 110, the IMD layer 120, the etching slowing layer 130, a portion of the etching stop layer 140, the lower electrode 150L and the upper electrode 150U, the MTJ layer 160, the first covering layer 171, the second covering layer 172, the third covering layer 173 and the fourth covering layer 174 are located at the memory region MR. The second conductive layer 110B and another portion of the etching stop layer 140 are located at the logic region LR.

In the present embodiment, the conductive layer 110 includes at least one first conductive portion 110A, at least one second conductive portion 110B and a dielectric layer 111, wherein the first conductive portion 110A and the second conductive portion 110B are formed within the dielectric layer 111 which is formed on the FEOL structure 11. The first conductive portion 110A and/or the second conductive portion 110B is, for example, a conductive via and/or a conductive trace. The conductive layer 110 may be defined as Mx, wherein the subscript “x” is positive integer equal to or greater than 1, for example, 1, 2, 3, 4, . . . , etc.

As illustrated in FIG. 1, the IMD layer 120 is formed over the conductive layer 110 and has a first etch rate. The etching slowing layer 130 has a second etch rate. The lower electrode 150L passes through the IMD layer 120 and the etching slowing layer 130. The MTJ layer 160 is formed on the lower electrode 150L. In an embodiment, the second etch rate is less than the first etch rate. As a result, a thickness T₁₂₀ of the IMD layer 120 may be thicker in comparison with a case of omitting the etching slowing layer 130, and the semiconductor structure 100 may have a smaller height H1 ranging between, for example, 1000 Å and 2000 Å, or 1400 Å and 1600 Å.

As illustrated in FIG. 1, the IMD layer 120 has a low etch resistance. The first etch rate of the IMD layer 120 is lower than the second etch rate of the etching slowing layer 130. In an embodiment, the second etch rate of the etching slowing layer 130 is six times (greater or less) that of the IMD layer 120. The IMD layer 120 may be formed from a material including, for example, silicon oxide. Due to the etching slowing layer 130, the IMD layer 120 has the thicker thickness T₁₂₀. In the present embodiment, the thickness T₁₂₀ of the IMD layer 120 may range between, for example, 50 angstrom (Å) and 500 Å, or be equal to or greater than 200 Å.

As illustrated in FIG. 1, the semiconductor structure 100 has a plurality of recesses 100r penetrate a plurality of layers to form a plurality of prominent structure including the upper electrode 150U, the MTJ layer 160, the lower electrode 150L and the etching slowing layer 130.

Furthermore, as illustrated in FIG. 1, after the recess 100r penetrating the upper electrode 150U, the MTJ layer 160, the lower electrode 150L, the spacer layer 135 and the etching slowing layer 130 is formed, the upper electrode 150U forms a lateral surface 150Us, the lower electrode 150L forms a lateral surface 150Ls, the MTJ layer 160 forms a lateral surface 160s, the spacer layer 135 forms a lateral surface 135s and the etching slowing layer 130 forms the lateral surface 130s. The lateral surface 150Us, the lateral surface 150Ls, the lateral surface 160s, the lateral surface 135s and the lateral surface 130s may be smoothly connected. In addition, the lateral surface 150Us, the lateral surface 150Ls, the lateral surface 160s, the lateral surface 135s and the lateral surface 130s may be curved-surfaces. Furthermore, adjacent two of the lateral surface 150Us, the lateral surface 150Ls, the lateral surface 160s, the lateral surface 135s and the lateral surface 130s may be smoothly connected. In addition, the lateral surface 150Us, the lateral surface 150Ls, the lateral surface 160s, the lateral surface 135s and the lateral surface 130s may be connected as a continuous curved-surface.

As illustrated in FIG. 1, the etching slowing layer 130 has a thickness T₁₃₀ ranges between, for example, 50 Å and 300 Å. In addition, the etching slowing layer 130 may be formed from a material including, for example, a-C, CN, AlOx, AlNx, WdC, WCN, etc.

As illustrated in FIG. 1, the spacer layer 135 is formed on the lateral surface 130s of the etching slowing layer 130 for preventing the etching slowing layer 130 from oxidating. The barrier layer 137 is formed between the lower electrode 150L and the spacer layer 135.

As illustrated in FIG. 1, the etching stop layer 140 is formed on the conductive layer 110. The etching stop layer 140 has a thickness T₁₄₀ ranging, for example, between 50 Å and 300 Å, for example, 125 Å, even greater or less. The etching stop layer 140 may be formed from a material including, for example, SiC, SiN, SiCN, etc. In addition, the total thickness Tt of the IMD layer 120 and the etching stop layer 140 may be equal to or greater than 325 Å, even greater or less.

As illustrated in FIG. 1, the upper electrode 150U is formed on the MTJ layer 160. The upper electrode 150U may be formed from a material including, for example, TiN, tungsten, etc. The lower electrode 150L may be formed from a material including, for example, TiN, tungsten, etc.

As illustrated in FIG. 1, in the present embodiment, the MTJ layer 160 has a Critical Dimension (CD) (for example, width) equal to or less than 65 nanometer (nm).

As illustrated in FIG. 1, the first covering layer 171 covers the etching slowing layer 130, the spacer layer 135, the lower electrode 150L, the MTJ layer 160 and the upper electrode 150U. The second covering layer 172 covers the first covering layer 171. The third covering layer 173 covers the second covering layer 172. The fourth covering layer 174 covers the third covering layer 173. In addition, the first covering layer 171 may be formed from a material including, for example, carbon, etc., the second covering layer 172 may be formed from a material including, for example, aluminum oxide (AlOx), etc., the third covering layer 173 may be formed from a material including, for example, carbon, etc., and the fourth covering layer 174 may be formed from a material the same a or similar to that of the first covering layer 171.

As illustrated in FIG. 1, the oxide layer 180 covers the fourth covering layer 174 and fills the recess 100r. The oxide layer 180 has at least one recess 180r to define or expose the logic region LR.

As illustrated in FIG. 1, the dielectric layer 185 covers the oxide layer 180 and fills the recess 180r. The dielectric layer 185 may be formed from a dielectric material with an extreme low dielectric constant (ELK). The dielectric layer 185 includes a first portion 1851 and a second portion 1852, wherein the first portion 1851 covers the oxide layer 180, and the second portion 1852 covers a covering portion 141 of the etching stop layer 140 which covers the second conductive portion 110B.

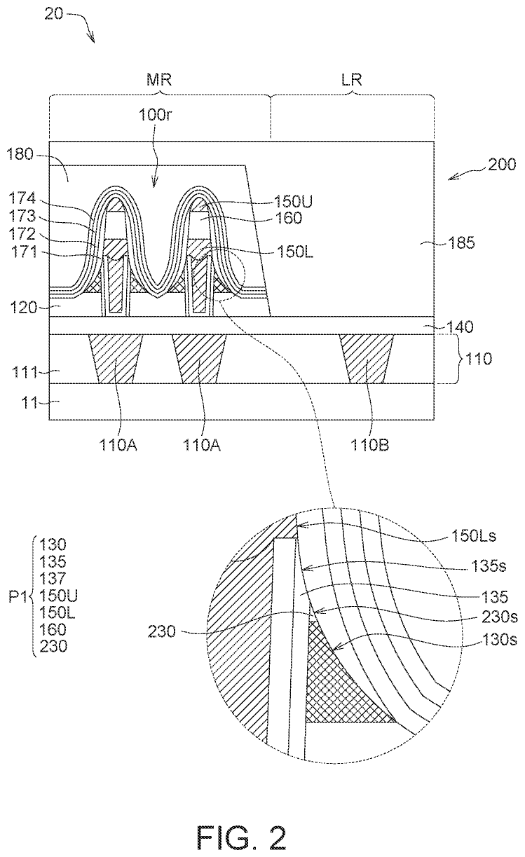

Referring to FIG. 2, FIG. 2 illustrates a schematic diagram of a cross-sectional view of a semiconductor device 20 according to another embodiment of the present disclosure.

As illustrated in FIG. 2, the semiconductor device 20 includes the FEOL structure 11 and a semiconductor structure 200 formed over the FEIOL structure 11. The semiconductor structure 200 is the BEOL structure or formed within the BEOL structure. The semiconductor structure 200 includes the conductive layer 110, the IMD layer 120, the etching stop layer 140 and a plurality of protrusions P1, a first covering layer 171, a second covering layer 172, a third covering layer 173, a fourth covering layer 174, an oxide layer 180 and a dielectric layer 185, wherein each protrusion P1 includes the etching slowing layer 130, a CMP (Chemical-Mechanical Planarization) stop layer 230, the spacer layer 135, the barrier layer 137, the lower electrode 150L, the upper electrode 150U and the MTJ layer 160.

As illustrated in FIG. 2, the semiconductor structure 200 includes the features the same as or similar to that of the semiconductor structure 100, and difference is that the semiconductor structure 200 further includes the CMP stop layer 230.

As illustrated in FIG. 2, the CMP stop layer 230 may be formed from a material including, for example, SiON, NFARL (nitrogen free anti-reflection layer), SiO, etc.

As illustrated in FIG. 2, after the recess 100r penetrating the upper electrode 150U, the MTJ layer 160, the lower electrode 150L, the spacer layer 135, the CMP stop layer 230 and the etching slowing layer 130 is formed, the upper electrode 150U forms the lateral surface 150Us, the lower electrode 150L forms the lateral surface 150Ls, the MTJ layer 160 forms the lateral surface 160s, the spacer layer 135 forms the lateral surface 135s, the CMP stop layer 230 forms a lateral surface 230s and the etching slowing layer 130 forms the lateral surface 130s. The lateral surface 150Us, the lateral surface 150Ls, the lateral surface 160s, the lateral surface 135s and the lateral surface 130s may be smoothly connected. In addition, the lateral surface 150Us, the lateral surface 150Ls, the lateral surface 160s, the lateral surface 135s, the lateral surface 230s and the lateral surface 130s may be curved-surfaces. Furthermore, adjacent two of the lateral surface 150Us, the lateral surface 150Ls, the lateral surface 160s, the lateral surface 135s and the lateral surface 130s may be smoothly connected. In addition, the lateral surface 150Us, the lateral surface 150Ls, the lateral surface 160s, the lateral surface 135s, the lateral surface 230s and the lateral surface 130s may be connected as a continuous curved-surface.

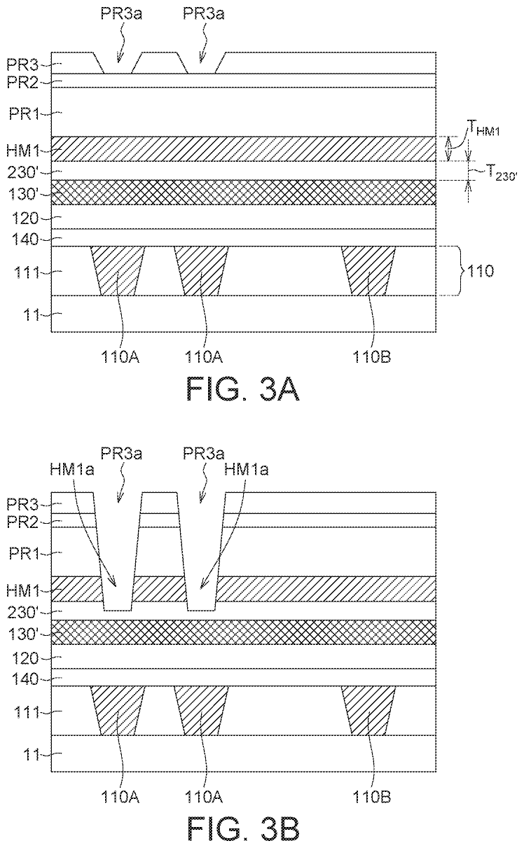

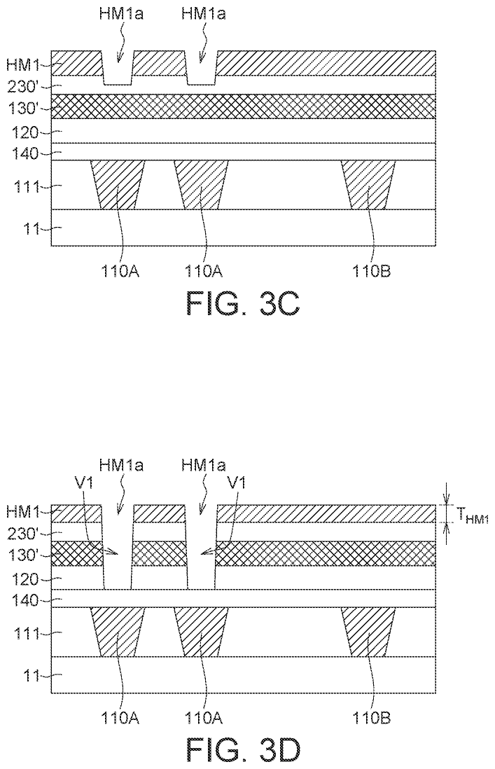

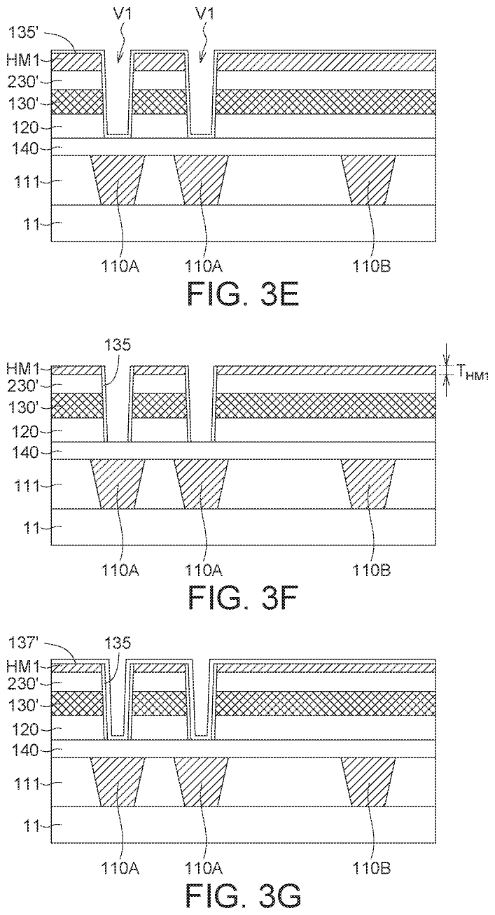

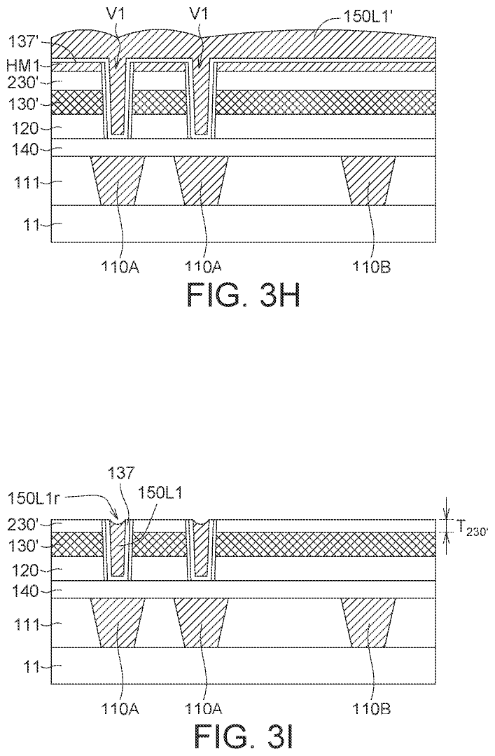

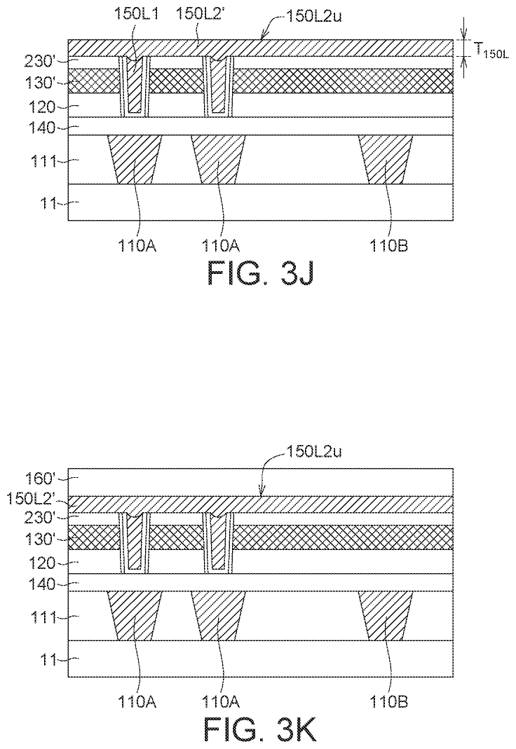

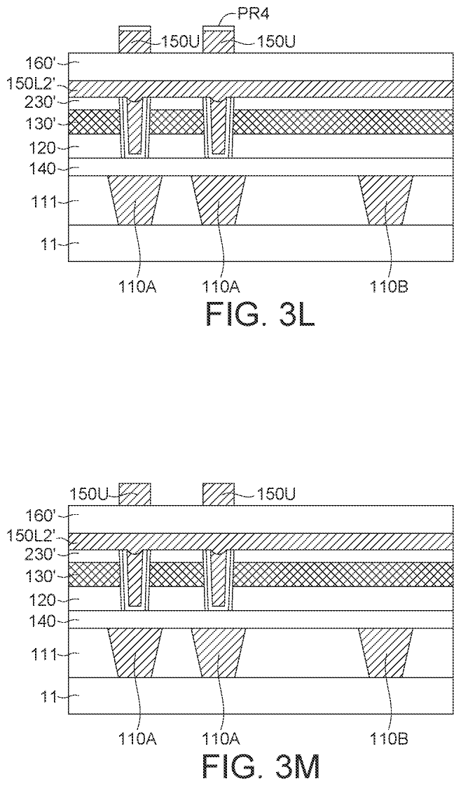

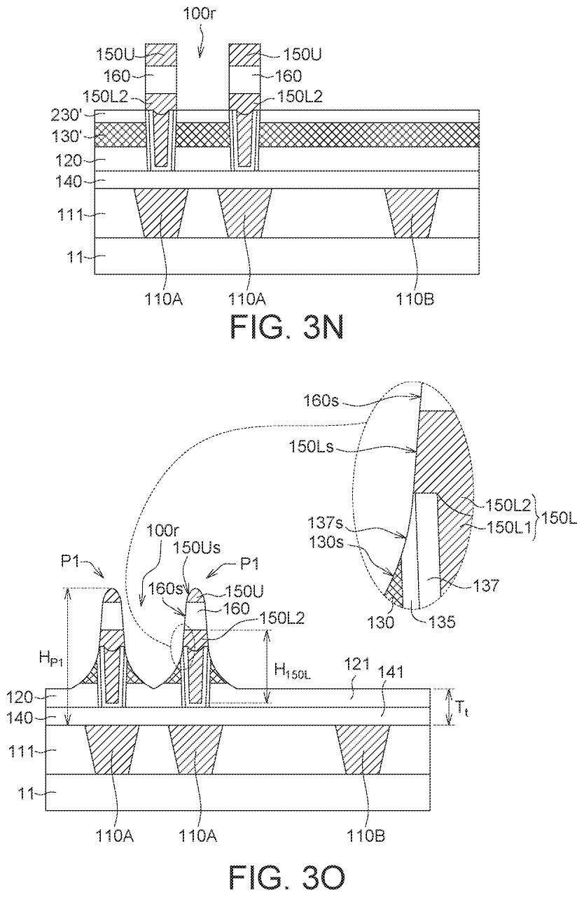

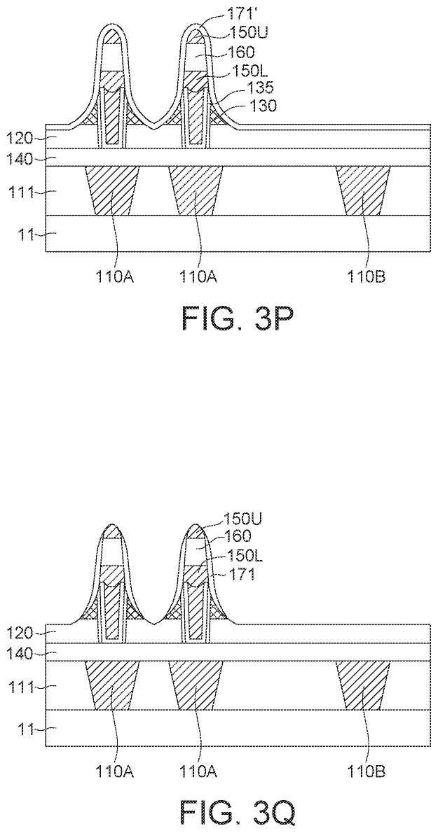

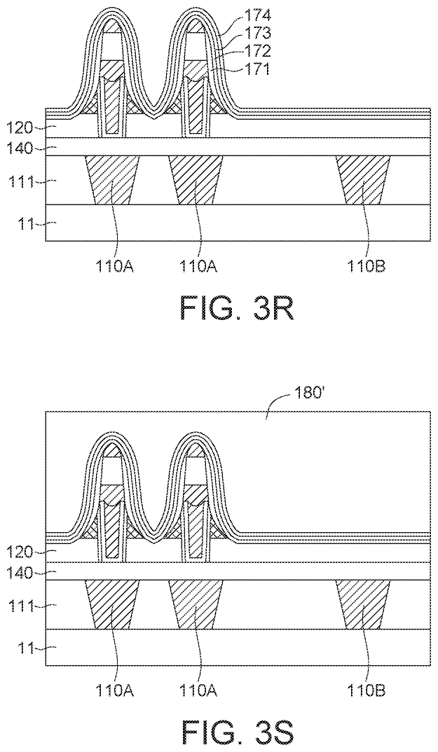

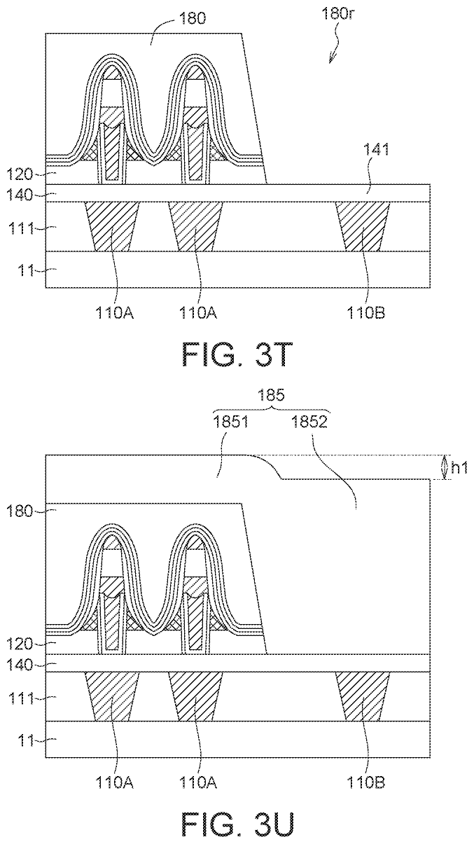

Referring to FIGS. 3A to 3U, FIGS. 3A to 3U illustrate schematic diagrams of manufacturing processes of the semiconductor device 10 in FIG. 1.

As illustrated in FIG. 3A, the first conductive layers 110 including at least one first conductive portion 110A, at least one second conductive portion 110B and a dielectric layer 111 is formed, wherein the first conductive portion 110A and the second conductive portion 110B are formed in the dielectric layer 111 which is formed on the FEOL structure 11. The etching stop layer 140, the IMD layer 120, an etching slowing layer material 130′, a CMP stop layer material 230′, a hard mask HM1, a first photoresistor PR1, a second photoresistor PR2 and a third photoresistor PR3 are formed on the conductive layer 110 in order. The third photoresistor PR3 may be patterned by using, for example, photolithography (exposure/etching/development). The third photoresistor PR3 has at least one opening PR3a exposing the second photoresistor PR2.

In FIG. 3A, the hard mask HM1 may be formed from a material including, for example, TiN, etc. The hard mask HM1 has a thickness T_{HM1} ranges between 150 Å and 250 Å, for example, 200 Å. The CMP stop layer material 230′ may be formed from a material including, for example, SiON, NFARL, SiO, etc. The CMP stop layer material 230′ has a thickness T_{230′} ranges between 50 Å and 300 Å, for example, 200 Å.

As illustrated in FIG. 3B, at least one opening HM1a penetrating the second photoresistor PR2, the first photoresistor PR1, the hard mask HM1 and a portion of the CMP stop layer material 230′ is formed through the opening PR3a by using, for example, dry etching.

As illustrated in FIG. 3C, the first photoresistor PR1, the second photoresistor PR2 and the third photoresistor PR3 are removed to expose the hard mask HM1 by using, for example, ashing.

As illustrated in FIG. 3D, at least one through hole V1 penetrate the CMP stop layer material 230′ and the IMD layer 120 to expose the etching stop layer 140 is formed by using, for example, dry etching. After the through holes V1 are formed, the thickness T_{HM1} of the hard mask HM1 is reduced to, for example, 110 Å, even greater or less.

As illustrated in FIG. 3E, a spacer layer material 135′ covering bottom surface and sidewalls of the through hole V1 and an upper surface of the hard mask HM1 is formed by using, for example, deposition, such as CVD (chemical vapor deposition), PVD (physical vapor deposition), etc. The spacer layer material 135′ may be formed from a material including, for example, SiN, etc.

As illustrated in FIG. 3F, a portion of the spacer layer material 135′ is removed by using, for example, wet cleaning, and a remaining portion (the spacer layer 135) of the spacer layer material 135′ covers the lateral surface of the etching slowing layer material 130′ for protecting the etching slowing layer material 130′ from oxidating. After removed, the thickness T_{HM1} of the hard mask HM1 is reduced to 90 Å.

As illustrated in FIG. 3G, a barrier layer material 137′ over the spacer layer 135 and an upper surface of the etching stop layer 140 is formed by using, for example, deposition.

As illustrated in FIG. 3H, a first lower electrode material 150L1′ filling the through hole V1 and covering the barrier layer material 137′ is formed by using, for example, deposition, such as MOCVD (Metal-organic Chemical Vapor Deposition), etc.

As illustrated in FIG. 3I, a portion of the first lower electrode material 150L1′, the entirety of the hard mask HM1, a portion of the CMP stop layer material 230′ and a portion of the barrier layer material 137′ are removed by using, for example, a CMP, wherein a remaining portion (a first lower electrode layer 150L1) of the first lower electrode material 150L1′ is formed within the through hole V1, and a remaining portion of the barrier layer material 137′ forms the barrier layer 137. The planarization process may stop at the CMP stop layer material 230′, wherein the CMP stop layer material 230′ may protect the below etching slowing layer material 130′ from being removed. After CMP, the thickness T_{230′} is reduced to, for example, 50 Å, even greater or less. After CMP, the first lower electrode layer 150L1 formed within the through hole V1 forms a recess 150L1r.

As illustrated in FIG. 3J, a second lower electrode material 150L2′ over the first lower electrode layer 150L1 and the CMP stop layer material 230′ is formed by using, for example, deposition, such as MOCVD, etc. and the second lower electrode material 150L2′ may be planarized by using CMP. After CMP, the second lower electrode material 150L2′ forms an upper surface 150L2u, wherein the upper surface 150L2u is a plane which is conducive to forming a high-quality MTJ structure. After CMP, the second lower electrode material 150L2′ has a thickness T_{150L} ranging between, for example, 50 Å and 110 Å, even greater or less.

As illustrated in FIG. 3K, the MTJ layer structure 160′ is formed on the upper surface 150L2u of the second lower electrode material 150L2′.

As illustrated in FIG. 3L, an upper electrode material over the MTJ layer structure 160′ is formed by using, for example, lithography, etc., and then a patterned photoresistor PR4 in FIG. 3L covering the upper electrode material. Then, the upper electrode material is patterned through the patterned photoresistor PR4 to form at least one upper electrode 150U as illustrated in FIG. 3L.

As illustrated in FIG. 3M, the patterned photoresistor PR4 in FIG. 3L is removed to expose the upper electrode 150U by using, for example, etching.

As illustrated in FIG. 3N, at least one recess 100r penetrating the MTJ layer structure 160′ and the second lower electrode material 150L2′ are formed to form at least one MTJ layer 160 and at least one second lower electrode layer 150L2 by using, for example, dry etching.

As illustrated in FIG. 3O, the recess 100r is continuously deepened to penetrate the CMP stop layer material 230′, the etching slowing layer material 130′ and a portion of the IMD layer 120 to form a plurality of a plurality of protrusions P1, wherein each protrusion P1 includes the etching slowing layer 130, the spacer layer 135, the barrier layer 137, the lower electrode 150L, the upper electrode 150U and the MTJ layer 160. In the same process, a sidewall of the upper electrode 150U, an sidewall of the MTJ layer 160, an sidewall of the second lower electrode layer 150L2, an sidewall of the barrier layer 137 and an sidewall of the etching slowing layer 130 are etched/trimmed, as illustrated in FIG. 3O. After the recess 100r or the protrusion P1 is formed, the upper electrode 150U forms the lateral surface 150Us, the MTJ layer 160 forms the lateral surface 160s, the second lower electrode layer 150L2 forms the lateral surface 150Ls, the spacer layer 135 forms the lateral surface 135s and the etching slowing layer 130 forms the lateral surface 130s. The etched lateral surface 160s of the MTJ layer 160 may provide a high-quality surface property. The lateral surface 150Us, the lateral surface 150Ls, the lateral surface 160s, the lateral surface 135s and the lateral surface 130s may be smoothly connected. In addition, the lateral surface 150Us, the lateral surface 150Ls, the lateral surface 160s, the lateral surface 135s and the lateral surface 130s may be curved-surfaces. Furthermore, adjacent two of the lateral surface 150Us, the lateral surface 150Ls, the lateral surface 160s, the lateral surface 135s and the lateral surface 130s may smoothly connected. In addition, the lateral surface 150Us, the lateral surface 150Ls, the lateral surface 160s, the lateral surface 135s and the lateral surface 130s may be connected as a continuous curved-surface.

In FIG. 3O, the first lower electrode layer 150L1 and the second lower electrode layer 150L2 may form the lower electrode 150L. The lower electrode 150L has a height H_{150L} ranging between 525 Å and 725 Å, for example, 625 Å, even greater or less. In comparison with the lower electrode layer in a conventional semiconductor structure, the height H_{150L} of the lower electrode 150L is shorter, and thus the resistance of the lower electrode 150L is lower, the material amount of the lower electrode 150L is less and the cost of the material amount of the lower electrode 150L is also lower. In addition, in comparison with the lower electrode layer in a conventional semiconductor structure, a height H_{P1} from the conductive layer 110 to a top point of the protrusion P1 is less, for example, less than 1000 Å, for example. In addition, the total thickness Tt of the IMD layer 120 and the etching stop layer 140 may be equal to or greater than 325 Å, even greater or less.

During processes in FIGS. 3N and 3O, due to the etching slowing layer 130 having the second etch rate less than the first etch rate of the IMD layer 120, a covering portion 121 of the IMD layer 120 and the covering portion 141 of the etching stop layer 140 over the second conductive layer 110B will be not removed, and accordingly it may prevent the second conductive layer 110B from being exposed without any photo mask or lithography process. Furthermore, in comparison with a case of omitting the etching slowing layer 130, a photo mask is required to cover the covering portion 121 and the covering portion 141 for preventing the second conductive layer 110B from being exposed due to over-etching.

As illustrated in FIG. 3P, the first covering layer material 171′ over the upper electrode 150U, the MTJ layer 160, the lower electrode 150L, the barrier layer 137, the etching slowing layer 130 and the IMD layer 120 is formed by using, for example, deposition.

As illustrated in FIG. 3Q, a portion of the first covering layer material 171′ is removed to form the first covering layer 171, wherein the first covering layer 171 exposes the IMD layer 120 and the upper electrode 150U.

As illustrated in FIG. 3R, the second covering layer 172, the third covering layer 173 and the fourth covering layer 174 over the first covering layer 171 are formed in order by using, for example, deposition.

As illustrated in FIG. 3S, an oxide layer material 180′ over the structure in FIG. 3R is formed by using, for example, deposition.

As illustrated in FIG. 3T, the recess 180r penetrating a portion of the oxide layer material 180′ and a portion of the IMD layer 120 is removed to form the oxide layer 180 by using, for example, lithography process. The oxide layer 180 may expose the covering portion 141 of the etching stop layer 140 which covers the second conductive layer 110B. In addition, the distance between an upper surface of the oxide layer 180 and an upper surface of the covering portion 141 may range between, for example, 500 Å and 1500 Å, or 1000 Å and 1500 Å.

As illustrated in FIG. 3U, the dielectric layer 185 in FIG. 1 over the oxide layer 180 is formed to form the semiconductor device 10 in FIG. 1 by using, for example, deposition.

As illustrated in FIG. 3T, the dielectric layer 185 including the first portion 1851 and the second portion 1852 is formed by using, for example, deposition, wherein the first portion 1851 covers the covering portion 141. The step h1 between the first portion 1851 and the second portion 1852 may be less than or not greater than, for example, 600 Å. Due to the step h1 being small enough resulted from the height of the MTJ structure being reduced, the CMP may be performed on the dielectric layer 185 for successfully planarizing the upper surface of the dielectric layer 185 without photo mask or lithography process. Furthermore, if the step h1 is too large (for example, greater than 600 Å), a photo mask is required to lower the first portion 1851.

As described above, due to the etching slowing layer 130, at least two photo masks (or lithography processes) may be omitted during the manufacturing processes of the semiconductor device.

The manufacturing method of the semiconductor device 20 includes the processes the same as or similar to that of the semiconductor device 10, and the difference is that a portion of the CMP stop layer 230 may be remained during the etching process in FIG. 3O.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor structure includes a conductive layer, an IMD layer formed on the conductive layer and having a first etch rate, and a plurality of protrusions. Each protrusion includes an etching slowing layer, a lower electrode and a MTJ layer, wherein the etching slowing layer is formed on the IMD layer and has a second etch rate, the lower electrode passes through the IMD layer and the etching slowing layer, and the MTJ layer is formed on the lower electrode. The second etch rate is less than the first etch rate. Accordingly, a thickness of the IMD layer may be thicker (in comparison with a case of omitting the etching slowing layer) for preventing a metal below the IMD layer from being exposed (also omitting a photo mask).

Example Embodiment 1: a semiconductor structure includes a conductive layer, an IMD layer and a plurality of protrusions. The IMD layer is formed on the conductive layer and has a first etch rate. Each protrusion includes an etching slowing layer, a lower electrode and a MTJ layer, wherein the etching slowing layer is formed on the IMD layer and has a second etch rate, the lower electrode passes through the IMD layer and the etching slowing layer, and the MTJ layer is formed on the lower electrode. The second etch rate is less than the first etch rate.

Example embodiment 2 based on Example embodiment 1: the etching slowing layer has a lateral surface which is curved-surface.

Example embodiment 3 based on Example embodiment 1: the etching slowing layer is formed from a material including a-C, CN, AlOx, AlNx, WdC or WCN.

Example embodiment 4 based on Example embodiment 1: each protrusion further includes a spacer layer covering a lateral surface of the etching slowing layer.

Example embodiment 5 based on Example embodiment 1: the IMD layer has a thickness equal to or greater than 200 Å.

Example embodiment 6 based on Example embodiment 1: the lower electrode has a height ranging between 525 Å and 725 Å.

Example embodiment 7: a semiconductor structure includes a conductive layer, an IMD layer and a plurality of protrusions. The IMD layer is formed on the conductive layer and has a first etch rate. Each protrusion includes an etching slowing layer, a CMP stop layer, a lower electrode and a MTJ layer, wherein the etching slowing layer is formed on the IMD layer and has a second etch rate, the CMP stop layer is formed on the etching slowing layer, the lower electrode passes through the CMP stop layer, the IMD layer and the etching slowing layer. MTJ layer is formed on the lower electrode. The second etch rate is less than the first etch rate.

Example embodiment 8 based on Example embodiment 7: each of the etching slowing layer and the CMP stop layer has a lateral surface, and the lateral surface of the etching slowing layer and the lateral surface of the CMP stop layer are connected to each other.

Example embodiment 9 based on Example embodiment 8: the lateral surface of the etching slowing layer and the lateral surface of the CMP stop layer are curved-surfaces.

Example embodiment 10 based on Example embodiment 7: the etching slowing layer is formed from a material including a-C, CN, AlOx, AlNx, WdC or WCN.

Example embodiment 11 based on Example embodiment 7: the IMD layer has a thickness equal to or greater than 200 Å.

Example embodiment 12 based on Example embodiment 7: the lower electrode has a height ranging between 525 Å and 725 Å.

Example embodiment 13: a manufacturing method of a semiconductor structure includes the following steps: forming an IMD layer on a conductive layer, wherein the IMD layer has a first etch rate; forming an etching slowing layer material on the IMD layer, wherein the etching slowing layer material has a second etch rate, wherein the second etch rate is less than the first etch rate; forming a lower electrode material on the etching slowing layer material; forming a MTJ layer structure on the lower electrode material; and forming a plurality of recesses to penetrate the MTJ layer structure, the lower electrode material, and the etching slowing layer material to form a plurality of protrusions, wherein each protrusion includes an etching slowing layer formed on the IMD layer, a lower electrode passing through the IMD layer and the etching slowing layer, and a MTJ layer formed on the lower electrode.

Example embodiment 14 based on Example embodiment 13: the semiconductor method further includes: forming a CMP stop layer material on the etching slowing material. In forming the recesses to penetrate the MTJ layer structure, the lower electrode material, and the etching slowing layer material to form the protrusions, the recesses further penetrate the CMP stop layer material, and each protrusion further includes a CMP stop layer formed on the etching slowing layer.

Example embodiment 15 based on Example embodiment 14: the semiconductor method further includes: forming a hard mask, wherein the hard mask has an opening; forming a through hole to penetrate the CMP stop layer material through the opening of the hard mask; and forming a spacer layer to cover a lateral surface of the etching slowing layer material.

Example embodiment 16 based on Example embodiment 14: the semiconductor method further includes: forming a through hole to penetrate the CMP stop layer material and the etching slowing layer material; and forming a lower electrode layer to fill the through hole.

Example embodiment 17 based on Example embodiment 13: the semiconductor method further includes: forming a CMP stop layer material on the etching slowing material. In forming the recesses to penetrate the MTJ layer structure, the lower electrode material, and the etching slowing layer material to form a plurality of protrusions, the recesses further penetrate the CMP stop layer materials, and the CMP stop layer material is fully removed.

Example embodiment 18 based on Example embodiment 13: in forming a plurality of recesses to penetrate the MTJ layer structure, the lower electrode material, and the etching slowing layer material to form a plurality of protrusions, the etching slowing layer forms a lateral surface which is a curved-surface.

Example embodiment 19 based on Example embodiment 13: the semiconductor method further includes: forming a CMP stop layer material on the etching slowing material. In forming the recesses to penetrate the MTJ layer structure, the lower electrode material, and the etching slowing layer material to form a plurality of protrusions, the recesses further penetrate the CMP stop layer material, and the CMP stop layer forms a lateral surface which is a curved-surface.

Example embodiment 20 based on Example embodiment 13: the semiconductor method further includes: forming a CMP stop layer material on the etching slowing material. In forming a plurality of recesses to penetrate the MTJ layer structure, the lower electrode material, and the etching slowing layer material to form a plurality of protrusions, the recesses further penetrate the CMP stop layer material, each of the CMP stop layer and the etching slowing layer forms a lateral surface, and the lateral surface of the etching slowing layer and the lateral surface of the CMP stop layer are connected to each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a conductive layer;
an intermetal dielectric (IMD) layer formed on the conductive layer and having a first etch rate; and
a plurality of protrusions each comprising:
an etching slowing layer formed on the IMD layer and having a second etch rate;
a lower electrode passing through the IMD layer and the etching slowing layer; and
a Magnetic Tunneling Junction (MTJ) layer formed on the lower electrode;
wherein the second etch rate is less than the first etch rate.

2. The semiconductor structure as claimed in claim 1, wherein the etching slowing layer has a lateral surface which is curved-surface.

3. The semiconductor structure as claimed in claim 1, wherein the etching slowing layer is formed from a material including a-C, CN, AlOx, AlNx, WdC or WCN.

4. The semiconductor structure as claimed in claim 1, wherein each protrusion further comprises:
a spacer layer covering a lateral surface of the etching slowing layer.

5. The semiconductor structure as claimed in claim 1, wherein the IMD layer has a thickness equal to or greater than 200 Å.

6. The semiconductor structure as claimed in claim 1, wherein the lower electrode has a height ranging between 525 Å and 725 Å.

7. A semiconductor structure, comprising:
a conductive layer;
an IMD layer formed on the conductive layer and having a first etch rate; and
a plurality of protrusions each comprising:
an etching slowing layer having a second etch rate;
a CMP stop layer formed on the etching slowing layer;
a lower electrode passing through the CMP stop layer, the IMD layer and the etching slowing layer; and
a MTJ layer formed on the lower electrode;
wherein the second etch rate is less than the first etch rate.

8. The semiconductor structure as claimed in claim 7, wherein each of the etching slowing layer and the CMP stop layer has a lateral surface, and the lateral surface of the etching slowing layer and the lateral surface of the CMP stop layer are connected to each other.

9. The semiconductor structure as claimed in claim 8, wherein the lateral surface of the etching slowing layer and the lateral surface of the CMP stop layer are curved-surfaces.

10. The semiconductor structure as claimed in claim 7, wherein etching slowing layer is formed from a material including a-C, CN, AlOx, AlNx, WdC or WCN.

11. The semiconductor structure as claimed in claim 7, wherein the IMD layer has a thickness equal to or greater than 200 Å.

12. The semiconductor structure as claimed in claim 7, wherein the lower electrode has a height ranging between 525 Å and 725 Å.

13. A manufacturing method of a semiconductor structure, comprising:
forming an IMD layer on a conductive layer, wherein the IMD layer has a first etch rate;
forming an etching slowing layer material on the IMD layer, wherein the etching slowing layer material has a second etch rate, wherein the second etch rate is less than the first etch rate;
forming a lower electrode material on the etching slowing layer material;
forming a MTJ layer structure on the lower electrode material; and
forming a plurality of recesses to penetrate the MTJ layer structure, the lower electrode material, and the etching slowing layer material to form a plurality of protrusions, wherein each protrusion comprises an etching slowing layer formed on the IMD layer, a lower electrode passing through the IMD layer and the etching slowing layer, and a MTJ layer formed on the lower electrode.

14. The semiconductor method as claimed in claim 13, further comprising:
forming a CMP stop layer material on the etching slowing material;
wherein in forming the recesses to penetrate the MTJ layer structure, the lower electrode material, and the etching slowing layer material to form the protrusions, the recesses further penetrate the CMP stop layer material, and each protrusion further comprises a CMP stop layer formed on the etching slowing layer.

15. The semiconductor method as claimed in claim 14, further comprising:
forming a hard mask, wherein the hard mask has an opening;
forming a through hole to penetrate the CMP stop layer material through the opening of the hard mask; and
forming a spacer layer to cover a lateral surface of the etching slowing layer material.

16. The semiconductor method as claimed in claim 14, further comprising:
forming a through hole to penetrate the CMP stop layer material and the etching slowing layer material; and
forming a lower electrode layer to fill the through hole.

17. The semiconductor method as claimed in claim 13, wherein further comprising:
forming a CMP stop layer material on the etching slowing material;
wherein in forming the recesses to penetrate the MTJ layer structure, the lower electrode material, and the etching slowing layer material to form a plurality of protrusions, the recesses further penetrate the CMP stop layer materials, and the CMP stop layer material is fully removed.

18. The semiconductor method as claimed in claim 13, wherein in forming a plurality of recesses to penetrate the MTJ layer structure, the lower electrode material, and the etching slowing layer material to form a plurality of protrusions, the etching slowing layer forms a lateral surface which is a curved-surface.

19. The semiconductor method as claimed in claim 13, further comprising:
forming a CMP stop layer material on the etching slowing material;
wherein in forming the recesses to penetrate the MTJ layer structure, the lower electrode material, and the etching slowing layer material to form a plurality of protrusions, the recesses further penetrate the CMP stop layer material, and the CMP stop layer forms a lateral surface which is a curved-surface.

20. The semiconductor method as claimed in claim 13, further comprising:
forming a CMP stop layer material on the etching slowing material;
wherein in forming a plurality of recesses to penetrate the MTJ layer structure, the lower electrode material, and the etching slowing layer material to form a plurality of protrusions, the recesses further penetrate the CMP stop layer material, each of the CMP stop layer and the etching slowing layer forms a lateral surface, and the lateral surface of the etching slowing layer and the lateral surface of the CMP stop layer are connected to each other.
